(19) United States
(12) Patent Application Publication
(10) Pub. No.: US 2026/0298723 A1
(43) Pub. Date: Oct. 1, 2026

(54) SELF-POWERED WIRELESS TELEMTRY FOR WAFER TEMPERATURE MEASUREMENTS

(71) Applicant: Siemens Corporation, Washington, DC (US)

(72) Inventors: Anand A. Kulkarni, Charlotte, NC (US); John Fraley, Fayetteville, AR (US)

(73) Assignee: Siemens Corporation, Washington, DC (US)

(21) Appl. No.: 19/489,922

(22) PCT Filed: Jun. 14, 2023
(86) PCT No.: PCT/US2023/025237

§ 371 Date: Dec. 4, 2025

(51) Int. Cl. G01K 1/024; G01K 1/02; G01K 7/20; G01K 7/21; H10P 72/00

(52) U.S. Cl. CPC G01K 1/024; G01K 1/026; G01K 7/203; G01K 7/21; G01K 2215/00; H10P 72/0602

(57) ABSTRACT

A telemetry system is configured to monitor temperature of a wafer disposed in a vacuum. The system can include a plurality of sensors configured to measure temperature at a plurality of locations across the wafer. The system can further include a plurality of sensor signal conditioning circuits. Each sensor signal conditioning circuit can be coupled to a respective sensor of the plurality of sensors. The plurality of sensor signal conditioning circuits can be configured to convert a resistance from each sensor of the plurality of sensors into low frequency sinusoids that define a respective frequency that is proportional to the resistance. The system can further include a multiplexor configured to generate a composite modulating signal from the low frequency sinusoids. The system can further include a frequency modulation (FM) transmitter configured to send the composite modulating signal outside of the vacuum.

### BACKGROUND

Various semiconductor applications require that the temperatures of the wafers are measured and monitored during fabrication. In various examples, the wafers are exposed to extreme environments, for instance temperatures around 650 degrees Celsius, thereby presenting challenges in accurately measuring temperatures across the wafers. It is recognized herein that current approaches to monitoring temperatures typically utilize contact thermocouples that physically connect to a given wafer and are hard-wired to a temperature measurement system.

### BRIEF SUMMARY

Embodiments of the invention address and overcome one or more of the described-herein shortcomings or technical problems by providing methods, systems, and apparatuses for accurately and wirelessly measuring temperatures across wafers in various extreme environments.

In an example aspect, a telemetry system is configured to monitor temperature of a wafer disposed in a vacuum. The system can include a plurality of sensors configured to measure temperature at a plurality of locations across the wafer. The system can further include a plurality of sensor signal conditioning circuits. Each sensor signal conditioning circuit can be coupled to a respective sensor of the plurality of sensors. The plurality of sensor signal conditioning circuits can be configured to convert a resistance from each sensor of the plurality of sensors into low frequency sinusoids that define a respective frequency that is proportional to the resistance. The system can further include a multiplexor configured to generate a composite modulating signal from the low frequency sinusoids. The system can further include a frequency modulation (FM) transmitter configured to send or transmit the composite modulating signal outside of the vacuum, wherein the composite modulating signal includes or indicates the temperature at each of the plurality of locations across the wafer. In some examples, the system includes a molten salt battery inside the vacuum. The molten salt battery can be configured to provide electrical power to the plurality of signal conditioning circuits, the multiplexor, and the transmitter. In various examples, the vacuum defines a temperature of at least 500 degrees Celsius. The system can further include an FM receiver located outside the vacuum, wherein the FM receiver is configured to receive the composite modulating signal from the FM transmitter within the vacuum. The FM transmitter can be configured to send the composite modulating signal at least one meter to the FM receiver outside the vacuum.

In an example, the plurality of sensors define a plurality of platinum resistive temperature devices. The system can further include a plurality of voltage controlled oscillators, wherein each voltage controlled oscillator is coupled to a respective platinum resistance temperature device of the plurality of platinum resistance temperature devices. Each voltage controlled oscillator can be configured to convert the resistance from the respective platinum resistance temperature device to the frequency that is based on the resistance. In particular, for example, each voltage controlled oscillator can be configured to generate a respective waveform within a respective frequency range that is different than frequency ranges generated by the other voltage controlled oscillators of the plurality of voltage controlled oscillators. For example, each voltage controlled oscillator can be configured to generate its respective waveform: at a first frequency when the platinum resistance temperature device is at a first resistance, and at a second frequency that is greater than the first frequency when the platinum resistance temperature device is at a second resistance that is greater than the first resistance. In such an example, the first and second frequencies are within the frequency range that corresponds to the respective voltage controlled oscillator.

### BRIEF DESCRIPTION OF THE DRAWINGS

The foregoing and other aspects of the present invention are best understood from the following detailed description when read in connection with the accompanying drawings. For the purpose of illustrating the invention, there is shown in the drawings embodiments that are presently preferred, it being understood, however, that the invention is not limited to the specific instrumentalities disclosed. Included in the drawings are the following Figures:

FIG. 1 is a block diagram of an example wafer that includes a plurality of locations at which temperature can be monitored and measured, in accordance with an example embodiment.

FIG. 2 is a block diagram that illustrates an example frequency division multiplexed (FDM) telemetry system configured to measure temperature of the wafer shown in FIG. 1 while the wafer is fabricated, wherein the FDM telemetry system defines a sensor multiplexing core and RF transmission circuitry.

FIG. 3 is a block diagram of the sensor multiplexing core and RF transmission circuitry, in accordance with an example embodiment.

FIG. 4 is a circuit diagram of an example voltage controlled oscillator (VCO) that can be part of the sensor multiplexing core and RF transmission circuitry illustrated in FIG. 3, in accordance with an example embodiment.

### DETAILED DESCRIPTION

As an initial matter, it is recognized herein that current approaches to obtaining temperature measurement data from wafers that are within a closed chamber in vacuum during semiconductor fabrication typically rely on sensors that are disposed on the wafer and hard-wired to a temperature measurement system outside the chamber. By way of example, the wafer might be 300 millimeters (mm), and there might be 64 sensors on the wafer.

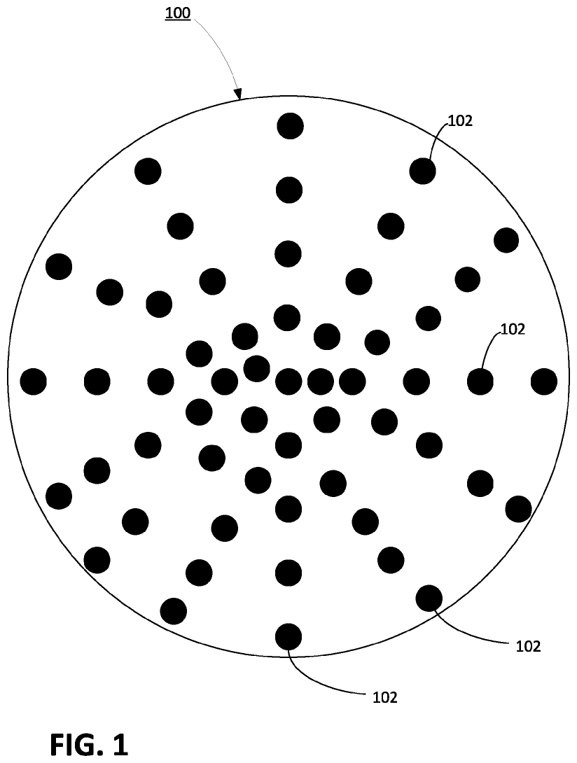

In accordance with various example embodiments, with reference to FIG. 1, temperature can be monitored wirelessly on a wafer, for instance a wafer 100, at a plurality of locations 102 across the wafer. In an example, the plurality of locations 102 define 64 locations, though it will be understood that the number and placement of locations 102 can vary as desired, and all such alternative locations are contemplated as being within the scope of this disclosure. For example, in some cases, a subset of the locations 102, for instance 16 of the locations 102, might be sufficient to monitor the temperature across the wafer 100. During temperature measurement, the wafer 100 can be enclosed in a vacuum, for instance a vacuum of about 5 millitorr that has a temperature of about 650 degrees Celsius (C).

It is recognized herein that, in various examples, monitoring wafers at high temperatures can be performed more simply and reliably using an analog approach as compared to a digital system. It is further recognized herein some advanced integrated circuits can perform at high temperatures, for instance operational amplifiers in silicon carbide (SiC), but they are often limited to 500° C., or less for practical operation. Further still, it is recognized herein that some transistors can function at 550° C. and even higher temperatures, for instance using by using wide bandgap electronics such as SiC and gallium nitride (GaN). Such transistors can include junction field effect transistors (JFETs) and high electron mobility transistors (HEMTs), as well as some ceramic based passive components to support the active components.

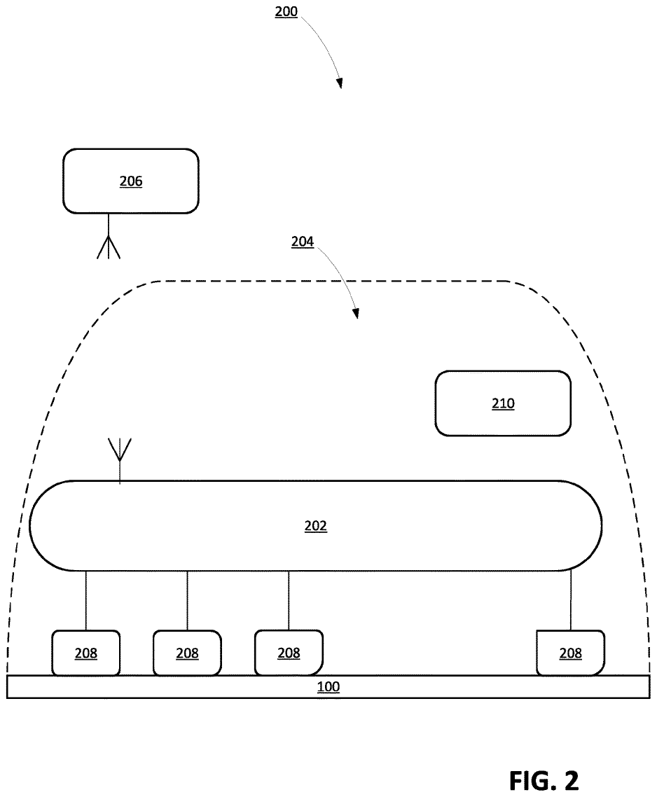

In various example embodiments, high temperature components, such as the components mentioned above, are combined and arranged in such a way so as to define a 16-channel high temperature wireless monitoring system for wafers. Referring to FIG. 2, an example frequency division multiplexed (FDM) telemetry system 200 can include a sensor multiplexing core and radio frequency (RF) transmission circuitry 202 configured to perform frequency modulation (FM) of a radio frequency (RF) carrier to wirelessly transmit data from a high temperature vacuum environment 204 to an RF receiver system 206. In various examples, the RF receiver system 206 is at room temperature, for instance at about 25° C., while the RF transmission circuitry 202 is in the high temperature environment 204, for instance at about 550° C. to 650° C. The distance between the RF receiver 206 and the RF transmission circuitry 202 can define several meters (m), for instance between 1 to 10 meters (e.g., 1.5 m), though it will be understood that the distance that the data travels from the RF transmission circuitry 202 and the RF receiver 206 can be alternatively configured, and all such alternative distances are contemplated as being within the scope of this disclosure.

With continuing reference to FIG. 2, the system 200, in particular the high temperature vacuum environment 204, can include a wafer that is monitored at various locations on the wafer, for instance the wafer 100 that can be monitored at a subset of the plurality of locations 102. In particular, for example, a plurality of temperature sensors 208, such as a platinum resistive temperature device (RTD) or other temperature variable impedance device can be disposed at each location 102 in the subset of locations, so as to be configured to measure temperature at each subset location, for instance 16 locations, of the plurality of locations 102. By way of example, and without limitation, the sensors 208 may include other temperature variable impedance devices such as capacitors with a type 2 dielectrics that define a non-linear temperature coefficient, which generally decrease in capacitance as temperature increases over a given temperature range. It is recognized herein that most semiconductors, such as silicon, exhibit a negative temperature coefficient of resistance, such that the resistivity of the bulk semiconductor decreases with increasing temperature.

In various examples, the system 200 can include a molten salt battery 210 configured to deliver power to the system 200, in particular to the sensors 208 and the sensor multiplexing core and RF transmission circuitry 202. The battery 210 can define a high energy density configured to operate at temperatures at which their salts become molten, for example temperatures above 300° C. In particular, for example, a sodium sulfur molten salt battery that does not operate until the salt becomes molten can operate when the temperature (e.g., 300° C.) required for the salt to become molten and the electronics to function is exceeded. The battery 210 can be configured to deliver power at least 100 hours, for instance 1000 hours or more, depending on the particular chemistry and geometry of the battery 210. Alternatively, or additionally, the system 200 can define a power source that is delivered wirelessly to the sensor multiplexing core and RF transmission circuitry 202. For example, power can be delivered wirelessly at a radio or optical frequency. In some cases, the system 200 defines a resonant induced power system capable of transmitting and receiving power, so as to wirelessly power the transmitter (RF transmission circuitry 202) of the sensors 208.

With continuing reference to FIG. 2, in an example, the wafer 100 can reside in the vacuum environment 204 at temperatures up to about 650° C. The sensor multiplexing core and RF transmission circuitry 202 can be communicatively coupled to a plurality of sensors 208, so as to define a plurality of sensor inputs. The sensor multiplexing core and RF transmission circuitry 202 can be configured to process the plurality of sensor inputs, for instance 16 sensor inputs, from the sensors 208. The sensor multiplexing core and RF transmission circuitry 202 can further be configured to wireless transmit data that is received from the sensors 208 (e.g., sensor inputs). In particular, the data can be transmitted several meters, for instance 1.5 m, to the RF receiver 206 that is outside the vacuum environment 204.

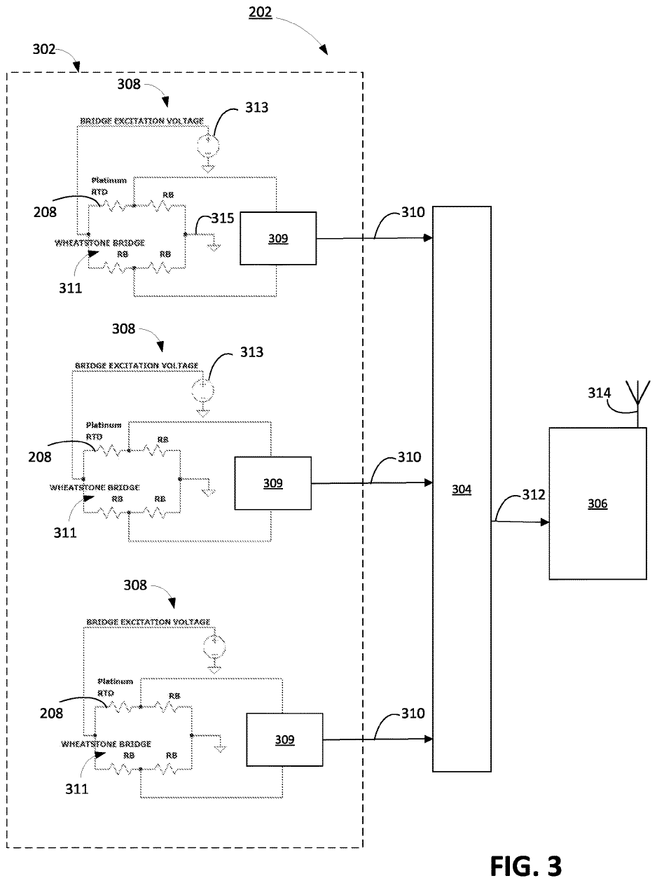

Referring also to FIG. 3, the sensor multiplexing core and RF transmission circuitry 202 can define various circuitry configured to process and transmit data from the sensors 208. In particular, for example, the sensor multiplexing core and RF transmission circuitry 202 can include a signal conditioning system 302, a frequency division multiplexor 304, and an FM radio transmitter circuit 306. The signal conditioning system 302 can include a plurality of sensor signal conditioning circuits 308. Each sensor signal conditioning circuit 308 can include a respective temperature sensor 208. In various examples, each temperature sensor 208 defines a platinum RTD or other temperature impedance device that defines a resistance. The signal conditioning system 302 can convert the resistance of the RTD or temperature impedance device into a low frequency sinusoid that defines a frequency that is proportional to the resistance.

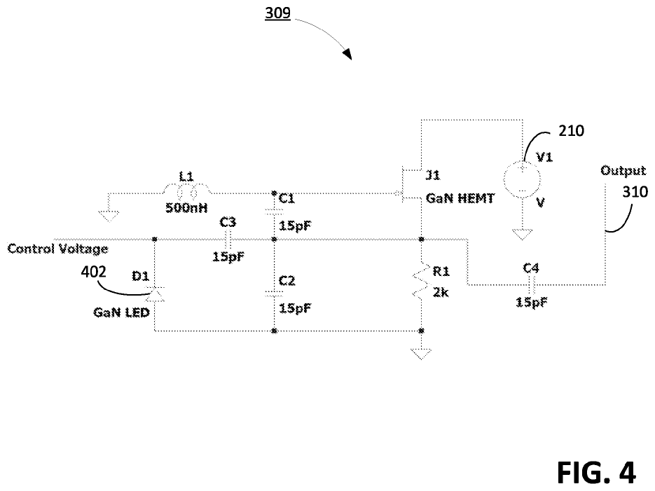

For example, with reference to FIGS. 3 and 4, each sensor signal conditioning circuit 308 can define a voltage controlled oscillator (VCO) 309. The VCO 309 can generate a signal 310 with an output frequency (f) that can be represented as

$$f = \frac{1}{2 π \times \sqrt{L C}} ,$$

where L Is total inductance of the sensor signal conditioning circuit 308, and C is the total capacitance of the circuit 308. The sensor 208, for instance a platinum RTD, can be configured in a Wheatstone bridge 311 defined by the sensor signal conditioning circuit 308. The RTD can be excited by a bridge excitation voltage 313, such that a change in temperature of the wafer 100 results in a changing resistance of the sensor (RTD) 208. The change in resistance of the RTD results in a voltage change across the bridge 311. In various examples, the sensor signal conditioning circuit 308 can include an instrumentation amplifier configured to amplify the change in voltage across the bridge 311. The output of the amplifier can be fed into the VCO 309, which can use the changing output voltage of the amplifier to drive a reverse-biased diode 402. In particular, for example, the changing voltage can result in a changing capacitance of the reverse-biased diode 402, thereby changing the total capacitance of the LC circuit and the frequency (f) of the output 310 of the VCO 309.

FIG. 3 shows three sensor signal conditioning circuits 308 for purposes of example, though it will be understood that the sensor conditioning system 302 can include additional sensor signal conditioning circuits 308, for instance 16 sensor signal conditioning circuits, and all such sensor conditioning systems 302 having alternative numbers of sensor signal conditioning circuits 308 are contemplated as being within the scope of this disclosure. Each sensor conditioning circuit can generate a respective output 310 that can be input into the frequency division multiplexer 304. The frequency division multiplexor 304 can add the outputs 310 together, so as to generate a composite modulating signal 312 that includes data from the outputs 310. Thus, the frequency division multiplexor 304 can modulate the signal 312 for wireless transmission based on the number of temperature sensors 208 being monitored. Each output 310 includes information from a respective sensor 208. Thus, the composite modulating signal 312 can include information from each of the sensors 208 on the wafer 100. The frequency divisional multiplexor 304 can feed the composite modulating signal 312 to the FM transmitter 306. The FM transmitter 306 can encode the information from the composite modulating signal 312, so as to define an encoded signal 314. The FM transmitter 306 can send the encoded signal wirelessly outside the vacuum environment 204, for instance to the FM receiver 206.

Thus, referring again to FIGS. 3 and 4, each sensor 208 (platinum RTD) is part of the respective circuit 308 that can convert a changing resistance of the respective RTD, which is due to a changing temperature of the wafer 100 (and thus the RTD), into a waveform of varying frequency (output 310). In particular, the VCO 309 can convert the changing resistance from the respective sensor 208. In various examples, each VCO 309 is configured to output a frequency that varies according to the temperature, and hence resistance, of the RTD feeding it, and each VCO 309 is configured to output a frequency that varies between separate ranges, so that the outputs 310 of the individual sensors each correspond to a unique frequency as compared to each other. By way example, and without limitation, a first RTD 208 can feed its VCO 309 such that at 25° C., the frequency of the output 310 of its corresponding VCO 309 is 1 kHz, and at 600° C. the frequency of the output 310 of that same VCO 309 is 2 kHz. By way of further example, a second RTD 208 can feed its VCO 309 such that at 25° C., the frequency of the output 310 of its corresponding VCO 309 is 3 kHz, and at 600° C. the frequency of the output 310 of that same VCO 309 is 4 kHz. Thus, each VCO 309 can define its own frequency range that differs from the other VCOs 309. It will be understood that that 1 kHz is presented as an example range corresponding to the range of temperatures, and the respective output frequencies of the VCOs 309 can vary as desired so as to differ from each other and differ based on temperatures of the respective sensors 208, and all such frequency ranges are contemplated as being within the scope of this disclosure.

Still referring to FIG. 3, each output 310 of the VCO 309, and thus the sensor 208, can be fed into the frequency division multiplexor 304. The frequency division multiplexor 304 adds the various outputs 310 together into the single composite modulating signal 312. The signal 312 can be fed into the FM radio transmitter circuit 306, which can define a radio frequency VCO. In various examples, the radio frequency VCO generates the encoded signal 314 at 70 MHz, and broadcasts the signal 314 wirelessly to the receiver system 206, where the signal 314 can be received, demodulated, stored, analyzed, and the like. Referring in particular to FIG. 3, it will be understood that the VCO 309 is presented as an example, and that the various VCOs can include capacitors and inductors defining alternative, for instance larger, values that are suitable for sensor VCOs, and all such VCOs are contemplated as being within the scope of this disclosure. The VCOs, such as the example VCO 309, are capable of operation at various elevated temperatures, for instance 650° C. In particular, for example, the VCO 309 can include active devices that are made from wide band gap semiconductors, for instance silicon carbide (SiC), gallium nitride (GaN), etc. The VCO 309 can include a substrate, resistors, capacitors, and inductors that use ceramic thick film, so as to define a high temperature co-fired ceramic (HTCC) circuit constructed and tested to elevated temperatures. In various examples, the system 200 defines a high temperature sensor transmitter system that consumes power at a rate of less than 100 mW continuously for a time period, for instance from 12 to 24 hours. Furthermore, the system can measure temperature of the wafer 100 continuously, and process and wirelessly transmit related data and measured temperature information continuously, in accordance with various embodiments.

FIG. 2 illustrates an example of an environment within which embodiments of the present disclosure may be implemented. The system 200 can further include one or more processors for processing information. The processors may include one or more central processing units (CPUs), graphical processing units (GPUs), or any other processor known in the art. More generally, a processor as described herein is a device for executing machine-readable instructions stored on a computer readable medium, for performing tasks and may comprise any one or combination of, hardware and firmware. A processor may also comprise memory storing machine-readable instructions executable for performing tasks. A processor acts upon information by manipulating, analyzing, modifying, converting or transmitting information for use by an executable procedure or an information device, and/or by routing the information to an output device. A processor may use or comprise the capabilities of a computer, controller or microprocessor, for example, and be conditioned using executable instructions to perform special purpose functions not performed by a general purpose computer. A processor may include any type of suitable processing unit including, but not limited to, a central processing unit, a microprocessor, a Reduced Instruction Set Computer (RISC) microprocessor, a Complex Instruction Set Computer (CISC) microprocessor, a microcontroller, an Application Specific Integrated Circuit (ASIC), a Field-Programmable Gate Array (FPGA), a System-on-a-Chip (SoC), a digital signal processor (DSP), and so forth. Further, the processor(s) may have any suitable microarchitecture design that includes any number of constituent components such as, for example, registers, multiplexers, arithmetic logic units, cache controllers for controlling read/write operations to cache memory, branch predictors, or the like. The microarchitecture design of the processor may be capable of supporting any of a variety of instruction sets. A processor may be coupled (electrically and/or as comprising executable components) with any other processor enabling interaction and/or communication there-between. A user interface processor or generator is a known element comprising electronic circuitry or software or a combination of both for generating display images or portions thereof. A user interface comprises one or more display images enabling user interaction with a processor or other device.

Although specific embodiments of the disclosure have been described, one of ordinary skill in the art will recognize that numerous other modifications and alternative embodiments are within the scope of the disclosure. For example, any of the functionality and/or processing capabilities described with respect to a particular device or component may be performed by any other device or component. Further, while various illustrative implementations and architectures have been described in accordance with embodiments of the disclosure, one of ordinary skill in the art will appreciate that numerous other modifications to the illustrative implementations and architectures described herein are also within the scope of this disclosure. In addition, it should be appreciated that any operation, element, component, data, or the like described herein as being based on another operation, element, component, data, or the like can be additionally based on one or more other operations, elements, components, data, or the like. Accordingly, the phrase “based on,” or variants thereof, should be interpreted as “based at least in part on.”

Although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

What is claimed is:

1. A telemetry system configured to monitor temperature of a wafer disposed in a vacuum, the system comprising:
a plurality of sensors configured to measure temperature at a plurality of locations across the wafer;
a plurality of sensor signal conditioning circuits, each sensor signal conditioning circuit coupled to a respective sensor of the plurality of sensors, the plurality of sensor signal conditioning circuits configured to convert a resistance from each sensor of the plurality of sensors into low frequency sinusoids that define a respective frequency that is based on the resistance;
a multiplexor configured to generate a composite modulating signal from the low frequency sinusoids; and
a frequency modulation (FM) transmitter configured to send the composite modulating signal outside of the vacuum, wherein the composite modulating signal indicates the temperature at each of the plurality of locations across the wafer.

2. The telemetry system as recited in claim 1, the system further comprising:
a molten salt battery inside the vacuum, the molten salt battery configured to provide electrical power to the plurality of signal conditioning circuits, the multiplexor, and the transmitter.

3. The telemetry system as recited in claim 1, wherein the vacuum defines a temperature of at least 500 degrees Celsius.

4. The telemetry system as recited in claim 1, the system further comprising:
an FM receiver located outside the vacuum, the FM receiver configured to receive the composite modulating signal from the FM transmitter within the vacuum.

5. The telemetry system as recited in claim 1, wherein the FM transmitter is further configured to send the composite modulating signal at least one meter to the FM receiver outside the vacuum.

6. The telemetry system as recited in claim 1, wherein the plurality of sensors define a plurality of platinum resistive temperature devices.

7. The telemetry system as recited in claim 6, the system further comprising:
a plurality of voltage controlled oscillators, each voltage controlled oscillator coupled to a respective platinum resistance temperature device of the plurality of platinum resistance temperature devices.

8. The telemetry system as in claim 7, wherein each voltage controlled oscillator is configured to convert the resistance from the respective platinum resistance temperature device to the frequency that is based on the resistance.

9. The telemetry system as recited in claim 8, wherein each voltage controlled oscillator is configured to generate a respective waveform within a respective frequency range that is different than frequency ranges generated by the other voltage controlled oscillators of the plurality of voltage controlled oscillators.

10. The telemetry system as recited in claim 9, wherein each voltage controlled oscillator is configured to generate its respective waveform: at a first frequency when the platinum resistance temperature device is at a first resistance, and at a second frequency that is greater than the first frequency when the platinum resistance temperature device is at a second resistance that is greater than the first resistance.

11. The telemetry system as recited in claim 10, wherein the first and second frequencies are within the frequency range that corresponds to the respective voltage controlled oscillator.

12. A method for monitoring temperature of a wafer disposed in a vacuum, the method comprising:
measuring respective resistances, by each of a plurality of sensors, at a plurality of locations across the wafer;
converting resistances from each sensor of the plurality of sensors into low frequency sinusoids that define a respective frequency that is based on the respective resistance;
generating a composite modulating signal from the low frequency sinusoids; and
transmitting the composite modulating signal outside of the vacuum, wherein the composite modulating signal indicates the temperature at each of the plurality of locations across the wafer.

13. The method as recited in claim 12, wherein the plurality of sensors are coupled to a plurality of voltage controlled oscillators, the method further comprising:
generating, by each voltage controlled oscillator of the voltage controlled oscillators, a respective waveform within a respective frequency range that is different than frequency ranges generated by the other voltage controlled oscillators of the plurality of voltage controlled oscillators.

14. The method as recited in claim 13, the method further comprising:
each voltage controlled oscillator generating its respective waveform: at a first frequency when the sensor defines a first resistance, and at a second frequency that is greater than the first frequency when the sensor defines a second resistance that is greater than the first resistance.

15. The method as recited in claim 14, wherein the first and second frequencies are within the frequency range that corresponds to the respective voltage controlled oscillator.
